(19) United States
(12) Patent Application Publication
(10) Pub. No.: US 2025/0317139 A1
(43) Pub. Date: Oct. 9, 2025

(54) TRANSISTOR DEVICE HAVING A CAPACITIVE VOLTAGE DIVIDER CIRCUIT

(71) Applicant: Infineon Technologies Austria AG, Villach (AT)

(72) Inventors: Hyeongnam Kim, Chandler, AZ (US); Mohamed Imam, Tempe, AZ (US); Ziyang Xiao, Phoenix, AZ (US); Alexander Young, Scottsdale, AZ (US)

(21) Appl. No.: 18/629,386

(22) Filed: Apr. 8, 2024

(51) Int. Cl. H03K 17/56; H01L 29/20; H01L 29/778

(52) U.S. Cl. CPC H03K 17/56; H10D 30/475; H10D 62/8503

(57) ABSTRACT

A transistor device includes: a substrate; an epitaxial layer stack formed on the substrate, the epitaxial layer stack including a heterojunction between two epitaxial layers having different band gaps, the heterojunction defining a channel region of the transistor device; a source terminal electrically connected to a source region of the epitaxial layer stack; a drain terminal electrically connected to a drain region of the epitaxial layer stack; a gate terminal electrically connected to a gate structure laterally between the source region and the drain region; a substrate terminal electrically connected to the substrate; and a capacitive voltage divider circuit electrically connected between the source region and the substrate. In a blocking state of the transistor device, the capacitive voltage divider circuit is configured to clamp the electric potential of the substrate to a positive value. Additional transistor device embodiments are described.

### BACKGROUND

Lateral III-nitride transistors are fabricated in an epitaxial structure. A vertical parasitic capacitor across the epitaxial structure causes unwanted hard and soft switching losses in the lateral III-nitride transistor, which becomes more critical at high frequencies. In addition, the lifetime of a III-nitride based lateral device depends on the quality of the epitaxial structure and the vertical voltage applied across the epitaxial structure. However, III-nitride epitaxial structures are typically grown on a foreign substrate such as Si, sapphire, SiC, or some other ceramic material. Accordingly, high-quality epitaxial structures are not easy to form. As a result, many defects are created in the epitaxial layers, degrading the fabrication yield and inducing a high early lifetime failure rate. It is especially difficult to achieve a sufficiently high yield of low-ohmic Ill-nitride transistors while also meeting stringent automotive application-level lifetime requirements.

Hence, there is a need for an improved Ill-nitride transistor design that is less susceptible to the vertical capacitor effects and has lower early lifetime failure rate.

### SUMMARY

According to an embodiment of a transistor device, the transistor device comprises: a substrate; an epitaxial layer stack formed on the substrate, the epitaxial layer stack including a heterojunction between two epitaxial layers having different band gaps, the heterojunction defining a channel region of the transistor device; a source terminal electrically connected to a source region of the epitaxial layer stack; a drain terminal electrically connected to a drain region of the epitaxial layer stack; a gate terminal electrically connected to a gate structure laterally between the source region and the drain region; a substrate terminal electrically connected to the substrate; and a capacitive voltage divider circuit electrically connected between the source region and the substrate, wherein in a blocking state of the transistor device, the capacitive voltage divider circuit is configured to clamp the electric potential of the substrate to a positive value.

According to another embodiment of a transistor device, the transistor device comprises: a substrate; an epitaxial layer stack formed on the substrate, the epitaxial layer stack including a heterojunction between two epitaxial layers having different band gaps, the heterojunction defining a channel of the transistor device; a source terminal electrically connected to a source region of the epitaxial layer stack; a drain terminal electrically connected to a drain region of the epitaxial layer stack; a gate terminal electrically connected to a gate structure laterally between the source region and the drain region; a substrate terminal electrically connected to the substrate; and a capacitive voltage divider circuit electrically connected between the source region and the substrate, wherein the capacitive voltage divider circuit comprises a chain of diodes electrically connected from the substrate to the source region in a forward direction and/or a capacitor electrically connected between the substrate and the source region.

According to an embodiment of a transistor device, the transistor device comprises: a substrate; an epitaxial layer stack formed on the substrate, the epitaxial layer stack including a heterojunction between two epitaxial layers having different band gaps, the heterojunction defining a channel of the transistor device; a source terminal electrically connected to a source region of the epitaxial layer stack; a drain terminal electrically connected to a drain region of the epitaxial layer stack; a gate terminal electrically connected to a gate structure laterally between the source region and the drain region; a substrate terminal electrically connected to the substrate; and a discharge diode device electrically connected from the substrate to the source region in a reverse direction, wherein the discharge diode device is configured to discharge a negative potential on the substrate when the transistor device switches from off to on.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1A illustrates a circuit schematic of a transistor device having a capacitive voltage divider circuit.

FIG. 1B illustrates a cross-sectional perspective view of the transistor device.

FIG. 2 illustrates a circuit schematic of a voltage clamp device of the capacitive voltage divider circuit, according to an embodiment.

FIG. 3 illustrates a circuit schematic of the voltage clamp device, according to another embodiment.

FIG. 4 illustrates a circuit schematic of a discharge diode device of the capacitive voltage divider circuit, according to an embodiment.

FIGS. 5 through 14 each illustrate a circuit schematic of the capacitive voltage divider circuit, according to additional embodiments.

### DETAILED DESCRIPTION

Embodiments described herein provide a transistor device that includes an epitaxial layer stack formed on a substrate. The epitaxial layer stack includes a heterojunction between two epitaxial layers having different band gaps, where the heterojunction defines a channel region of the transistor device. The transistor device also includes a capacitive voltage divider circuit electrically connected between the source region and the substrate. A voltage clamp device of the capacitive voltage divider circuit clamps the electric potential of the substrate to a positive value in a blocking state of the transistor device. A discharge diode device of the capacitive voltage divider circuit discharges a negative potential on the substrate when the transistor device switches from off to on. The capacitive voltage divider circuit may include the voltage clamp device but not the discharge diode device, the discharge diode device but not the voltage clamp device, or both the voltage clamp device and the discharge diode device.

The capacitive voltage divider circuit reduces the parasitic vertical capacitance and the vertical voltage drop across the epitaxial layer stack formed on the substrate. As a result, the switching efficiency and overall lifetime of the transistor device is improved. The reduction of the vertical voltage across the epitaxial layer stack leads to suppression of buffer trapping under/near the drain contact at high drain voltage. Accordingly, a drain-side p-type GaN region is not necessary. Any increase in die (chip) size with the addition of the capacitive voltage divider circuit may be compensated by omitting the drain-side p-type GaN region, leading to cell pitch reduction where the cell pitch is the physical distance between adjacent transistor ‘cells’.

Described next with reference to the figures are embodiments of the transistor device.

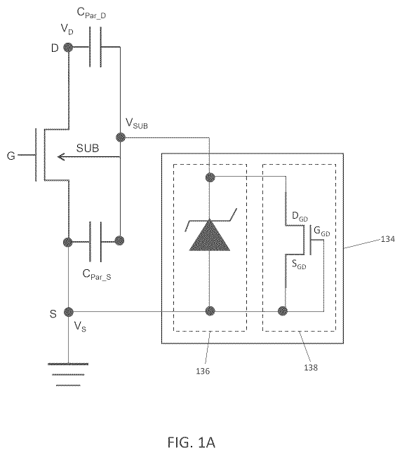

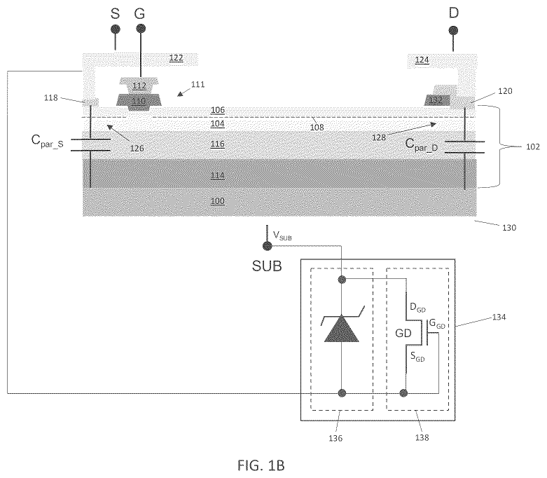

FIG. 1A illustrates a circuit schematic of the transistor device and FIG. 1B illustrates a cross-sectional perspective view of the transistor device. The transistor device includes a substrate (SUB) 100 that has a floating electric potential V_{SUB}. An epitaxial layer stack 102 formed on the substrate 100 includes a heterojunction between two epitaxial layers 104, 106 having different band gaps. For example, a lower type III-V semiconductor epitaxial layer 104 that partly defines the heterojunction may include intrinsic or lightly doped gallium nitride (GaN) and an upper type III-V semiconductor layer 106 that partly defines the heterojunction may include aluminum gallium nitride (AlGaN). More generally, any combination of type III-V semiconductor materials with different metallic contents can be used to provide a difference in bandgap.

The bandgap difference of the heterojunction defines an electrically conductive two-dimensional charge carrier gas channel region 108 which arises near an interface between the first type III-V semiconductor layer 104 and the second type III-V semiconductor layer 106 due to polarization effects. The channel region 108 may be interrupted to yield a normally-off device, e.g., by providing a p-type GaN region 110 as part of the device gate structure 111 which may also include a metallic gate (G) contact 112, or by another type of gate feature.

The semiconductor regions below the heterojunction do not directly contribute, in an electrical sense, to the provision of the electrically conductive channel region 108. In FIG. 1B, the substrate 100 may include or be formed from group IV or group III-V semiconductor materials. For example, the substrate 100 may be provided by a silicon or silicon-based wafer. A superlattice structure 114 may be formed on the substrate 100 and include a nucleation region such as a metal nitride (e.g., AlN), and a lattice transition region such as a number of semiconductor nitride (e.g., AlGaN) layers with a gradually diminishing metallic content, to enable the formation of relatively strain and defect free group IV semiconductor material thereon. An AlGaN back barrier 116 such as a C—AlGaN back barrier may be formed on the superlattice structure 114, below the lower type III-V semiconductor epitaxial layer 104 that partly defines the heterojunction. Respective metallic contacts 118, 120 are provided at the source(S) and drain (D) sides of the transistor device. The source and/or drain sides of the transistor device may also include a respective field plate 122, 124. The gate structure 111 may also include a field plate (not shown), which extends toward the drain side of the device.

The metallic source contact 118 forms or is part of a source terminal ‘S’ that is electrically connected to the source region 126 of the epitaxial layer stack 102. The metallic drain contact 120 forms or is part of a drain terminal ‘D’ that is electrically connected to the drain region 128 of the epitaxial layer stack 102. The metallic gate contact 112 forms or is part of a gate terminal ‘G’ that is electrically connected to the gate structure 111 laterally disposed between the source region 126 and the drain region 128. A substrate terminal ‘SUB’ is electrically connected to the substrate 100, which may have a backside metallic layer 130 to provide an Ohmic contact.

The transistor device is a lateral device in that the primary current flow path is along the channel region 108 between the source and drain regions 126, 128. In operation of the transistor device, the current flow may be bidirectional. The voltage blocking (between the source and drain) is unidirectional for high voltages (e.g., >400V) but bidirectional for low voltages (e.g., <20V). As used herein, voltage blocking refers to high-voltage blocking (e.g., >400V). For example, in the blocking state, the drain voltage V_{D} may be at a system voltage V_{BUS} of 400V or higher, e.g., 600V, 650V, or even higher. This means that the transistor device blocks 400V or more across drain-to-source in these examples.

The drain side of the transistor device may include an optional p-type GaN region 132. The optional p-type GaN region 132 or even the AlGaN back barrier 116 may generate holes at high voltage which can drift and damage the gate structure, inducing early lifetime failure. The transistor device also has a vertical parasitic capacitance, represented in FIGS. 1A and 1B by a source-side vertical parasitic capacitance C_{par_S} and a drain-side vertical parasitic capacitance C_{par_D}, that arises across the epitaxial layer stack 102. The vertical parasitic capacitance C_{par_S}, C_{par_D} induces unwanted switching losses and degrades overall efficiency of the transistor device. Defects, such as threading dislocations, point defects, etc., can accelerate the failure rate with a high voltage applied across the epitaxial layer stack 102.

To alleviate these problems, the transistor device in FIGS. 1A and 1B includes a capacitive voltage divider circuit 134 that is electrically connected between the source region 126 and the substrate 100. The transistor device operates as a switch by blocking the system voltage V_{BUS} at the drain terminal D of the main transistor device in a blocking (off) state and conducting system current in an on state. In the blocking state, the capacitive voltage divider circuit 134 clamps the electric potential V_{SUB} of the substrate 100 to a positive value.

For example, the transistor device may form or be part of a low-side switch device of a half bridge. The high-side switch device of the half bridge, which is not shown in FIGS. 1A and 1B, would have its source connected to the drain terminal D of the transistor device to form a switch node. When the high-side switch device is on, the drain voltage V_{D} of the low-side transistor device approximates the system voltage V_{BUS}, i.e., V_{D}˜ V_{BUS}. The capacitive voltage divider circuit 134 clamps the substrate potential V_{SUB} to 200V, e.g., so that the voltage difference between V_{D} and V_{SUB} remains sufficiently low and charging/discharging currents that occur during switching are effectively reduced, leading to improved overall efficiency.

In FIGS. 1A and 1B, the capacitive voltage divider circuit 134 includes a voltage clamp device 136 electrically connected from the substrate 100 to the source region 126 in a forward direction. That is, the anode of the voltage clamp device 136 is connected to the source region 126 and the cathode of the voltage clamp device 136 is connected to the substrate 100. The voltage clamp device 136 is illustrated as a Zener diode but is not necessarily implemented as a Zener diode. This illustration is intended to emphasize the Zener-like voltage clamping functionality of the voltage clamp device 136 in the blocking state of the transistor device.

As shown in FIGS. 1A and 1B, the capacitive voltage divider circuit 134 may also include a discharge diode device 138 in parallel with the voltage clamp device 136. The discharge diode device 138 discharges a negative potential (−V_{SUB}) on the substrate 100 when the transistor device switches from off to on. When the transistor device switches from off to on, the substrate 100 can be negatively charged and slowly discharges back toward OV without the discharge diode device 138, degrading the dynamic performance of the device. The discharge diode device 138 quickly releases the negative charge from the substrate 100 to improve the transistor dynamic behavior. The discharge diode device 138 enters an off (blocking) state once the negative voltage condition subsides.

In FIGS. 1A and 1B, the discharge diode device 138 is implemented as a gated diode GD, which is based on a transistor that has a source S_{GD} electrically connected to the source region 126 of the main transistor device, a drain D_{GD} electrically connected to the substrate 100, and a gate G_{GD} electrically connected to the source S_{GD} of the gated diode GD. The gate G_{GD} and source S_{GD} are tied together and act as the anode of the gated diode GS, whereas the drain D_{GD} acts as the cathode of the gated diode GS in FIGS. 1A and 1B. The gate G_{GD} of the gated diode GD instead may be electrically connected to the gate terminal G of the main transistor device. The gated diode GD discharges the negative potential (−V_{SUB}) on the substrate 100 when the main transistor device turns on, preventing depletion of the two-dimensional charge carrier gas channel region 108. The gate diode GD returns to a blocking (off) state once the negative voltage condition subsides.

As illustrated in subsequent figures, the discharge diode device 138 of the capacitive voltage divider circuit 134 may be implemented in different ways while still providing the negative substrate potential discharge functionality when the transistor device switches from off to on. The voltage clamp device 136 of the capacitive voltage divider circuit 134 also may be implemented in different ways while still providing the voltage clamping functionality in the blocking state of the transistor device.

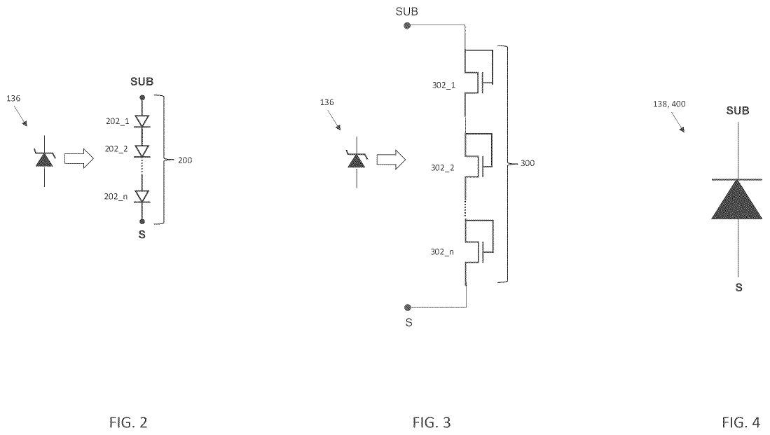

FIG. 2 illustrates a circuit schematic of the voltage clamp device 136, according to an embodiment. In FIG. 2, the voltage clamp device 136 includes a chain 200 of two or more p-GaN diodes 202 such as p-GaN/2DEG (two-dimensional electron gas) diodes electrically connected in series between the substrate (SUB) 100 and the source region(S) 126 of the main transistor device in a forward direction. The diode chain 200 is not used for its reverse blocking capability. Instead, the forward blocking capability of the diode chain 200 is used to provide clamping functionality, i.e., forward blocking configuration and not reverse blocking.

The anode of a first one 202_1 of the p-GaN diodes 202 in the chain 200 is electrically connected to the substrate (SUB) 100 and the cathode of a last one 202_n of the p-GaN diodes 202 in the chain 200 is electrically connected to the source region(S) 126 of the main transistor device. The clamping voltage provided by the chain 200 of p-GaN diodes 202 may be adjusted based on the number of the p-GaN diodes 202 included in the chain 200. The p-GaN diodes 202 may have, e.g., a forward voltage of ˜3V and the clamping voltage may be in a range of ˜3V to ˜300V. For example, a clamping voltage of ˜90V may be realized by including thirty p-GaN diodes 202 in the chain 200. A clamping voltage of ˜30V may be realized by including ten p-GaN diodes 202 in the chain 200. The clamping voltage also depends on the thickness of the epitaxial layer stack 102 and the system voltage V_{BUS}.

FIG. 3 illustrates a circuit schematic of the voltage clamp device 136, according to another embodiment. In FIG. 3, the voltage clamp device 136 includes a chain 300 of gated GaN diodes 302 electrically connected in series between the substrate (SUB) 100 and the source region(S) 126 of the main transistor device in the forward direction. As with the embodiment of FIG. 2, the diode chain 300 is not used for its reverse blocking capability. Instead, the forward blocking capability of the diode chain 300 is used to provide clamping functionality, i.e., forward blocking configuration and not reverse blocking.

The anode of a first one 302_1 of the gated GaN diodes 302 in the chain 300 is electrically connected to the substrate (SUB) 100 and the cathode of a last one 302_n of the gated GaN diodes 302 in the chain 300 is electrically connected to the source region(S) 126 of the main transistor device. The clamping voltage of the chain 300 of gated GaN diodes 302 may be adjusted based on the number of the gated GaN diodes 302 included in the chain 300. The gated GaN diodes 302 may have, e.g., a forward voltage of ˜1.5V and the clamping voltage may be in a range of ˜1.5V to ˜300V. For example, a clamping voltage of ˜90V may be realized by including sixty gated GaN diodes 302 in the chain 300. A clamping voltage of ˜30V may be realized by including twenty gated GaN diodes 302 in the chain 300. The clamping voltage also depends on the thickness of the epitaxial layer stack 102 and the system voltage V_{BUS}.

The voltage clamp device 136 may include a combination of the p-GaN diodes 202 shown in FIG. 2 and the gated GaN diodes 302 shown in FIG. 3. For example, the voltage clamp device 136 may include a chain of p-GaN diodes 202 and gated GaN diodes 302 electrically connected in series between the substrate (SUB) 100 and the source region(S) 126 of the main transistor device in the forward direction. The anode of a first one of the diodes 202/302 in the chain is electrically connected to the substrate (SUB) 100 and the cathode of a last one of the diodes 202/302 in the chain is electrically connected to the source region(S) 126 of the main transistor device.

FIG. 4 illustrates a circuit schematic of the discharge diode device 138, according to an embodiment. In FIG. 4, the discharge diode device 138 is a p-GaN diode 400 such as a p-GaN/2DEG diode electrically connected between the substrate (SUB) 100 and the source region(S) 126 of the main transistor device in a reverse direction, such that the p-GaN diode 400 discharges a negative potential (−V_{SUB}) on the substrate (SUB) 100 when the transistor device switches from off to on. The anode of the p-GaN diode 400 is electrically connected to the source region(S) 126 of the main transistor device and the cathode of the p-GaN diode 400 is electrically connected to the substrate (SUB) 100.

FIG. 5 illustrates a circuit schematic of the capacitive voltage divider circuit 134, according to another embodiment. In FIG. 5, the capacitive voltage divider circuit 134 further includes a capacitor 500 in parallel with the voltage clamp device 136 but omits the discharge diode device 138.

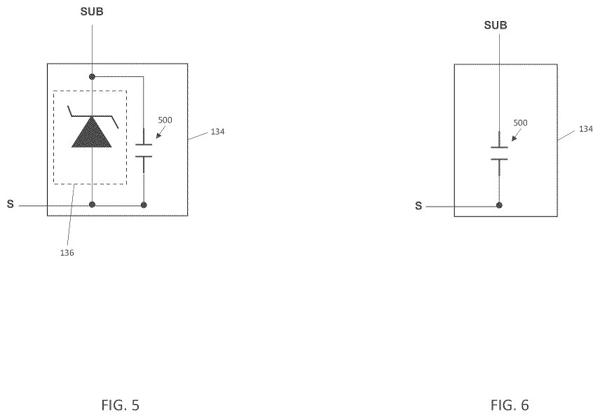

FIG. 6 illustrates a circuit schematic of the capacitive voltage divider circuit 134, according to another embodiment. The embodiment illustrated in FIG. 6 is similar to the embodiment in FIG. 5. In FIG. 6, the voltage clamp device 136 is omitted. According to this embodiment, the capacitor 500, which is electrically connected between the substrate (SUB) 100 and the source region(S) 126 of the main transistor device, is used instead of the voltage clamp device 136 to clamp the electric potential V_{SUB} of the substrate 100 to a positive value in the blocking state of the transistor device. The capacitance value of the capacitor 500 is selected to achieve the desired clamping voltage, e.g., ˜1.5V to ˜300V which depends on the thickness of the epitaxial layer stack 102 and the system voltage V_{BUS}. The capacitor 500 may be integrated with the transistor device in the same die (chip), e.g., using a MIM (metal-insulator-metal) capacitor. The capacitor 500 instead may be an external (e.g., discrete) device separate from the die that includes the transistor device.

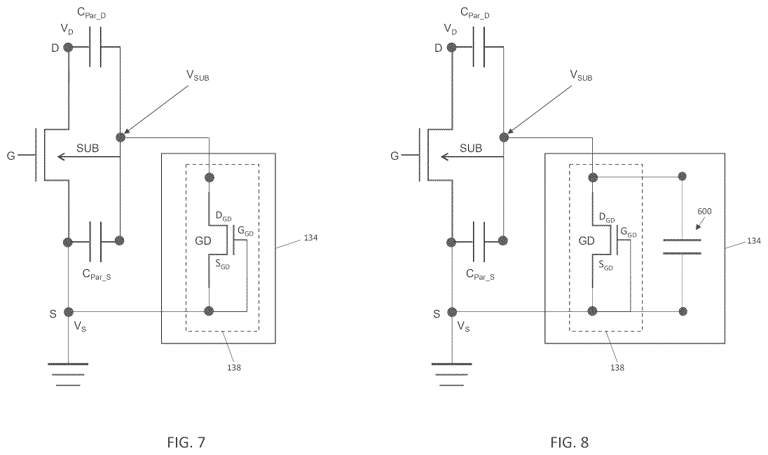

FIG. 7 illustrates a circuit schematic of the capacitive voltage divider circuit 134, according to another embodiment. The embodiment illustrated in FIG. 7 is similar to the embodiment in FIGS. 1A and 1B. In FIG. 7, the voltage clamp device 136 is omitted and the capacitive voltage divider circuit 134 includes just the discharge diode device 138. As previously explained herein, the discharge diode device 138 discharges the negative potential (−V_{SUB}) on the substrate 100 when the transistor device switches from off to on and may be implemented as a gated diode GD. The discharge diode device 138 is implemented as a gated diode GD in FIG. 7, with the source S_{GD} of the gated diode GD electrically connected to the source(S) region 126 of the main transistor device, the drain D_{GD} of the gated diode GD electrically connected to the substrate 100, and the gate G_{GD} of the gated diode GD electrically connected to the source S_{GD} of the gated diode. The gate G_{GD} of the gated diode GD instead may be electrically connected to the gate terminal G of the main transistor device.

FIG. 8 illustrates a circuit schematic of the capacitive voltage divider circuit 134, according to another embodiment. The embodiment illustrated in FIG. 8 is similar to the embodiment in FIG. 7. In FIG. 8, the capacitive voltage divider circuit 134 also includes a capacitor 600 in parallel with the discharge diode device 138.

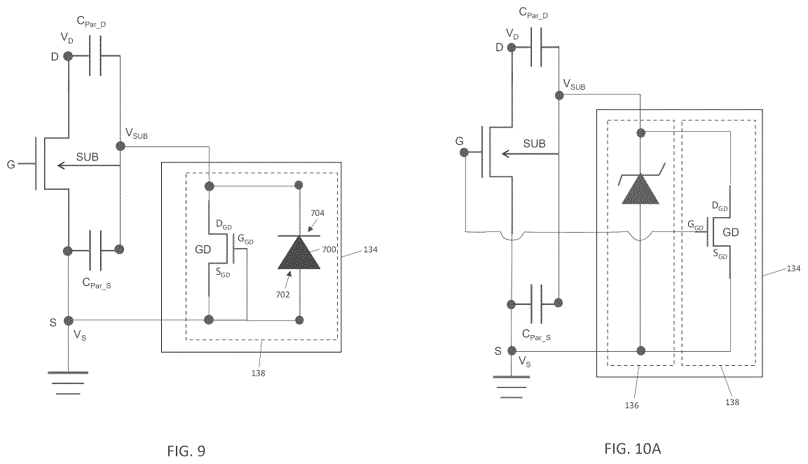

FIG. 9 illustrates a circuit schematic of the capacitive voltage divider circuit 134, according to another embodiment. The embodiment illustrated in FIG. 9 is similar to the embodiment in FIG. 8. In FIG. 9, the discharge diode device 138 is implemented as a p-GaN diode 700 in parallel with a gated diode GD. The anode 702 of the p-GaN diode 700 is electrically connected to the source(S) region 126 of the main transistor device. The cathode 704 of the p-GaN diode 700 is electrically connected to the substrate (SUB) 100.

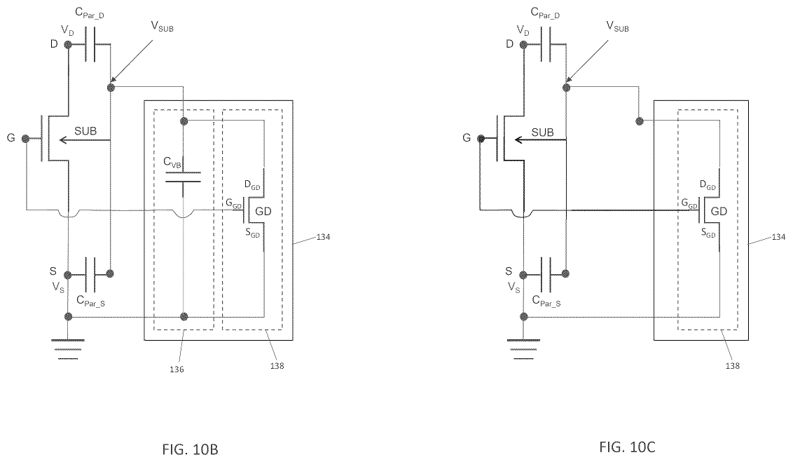

FIGS. 10A through 10C illustrate circuit schematics of the capacitive voltage divider circuit 134, according to further embodiments. The embodiment illustrated in FIG. 10A is similar to the embodiment in FIGS. 1A and 1B. In FIG. 10A, the gate G_{GD} of the gated diode GD is electrically connected to the gate terminal G of the main transistor device instead of the source region(S) region 126 of the main transistor device. The embodiment illustrated in FIG. 10B is similar to the embodiment in FIG. 10A except that the voltage clamp device 136 is implemented using a capacitor C_{VB} instead of a diode. The embodiment illustrated in FIG. 10C is similar to the embodiments in FIGS. 10A and 10B except that the voltage clamp device 136 is omitted.

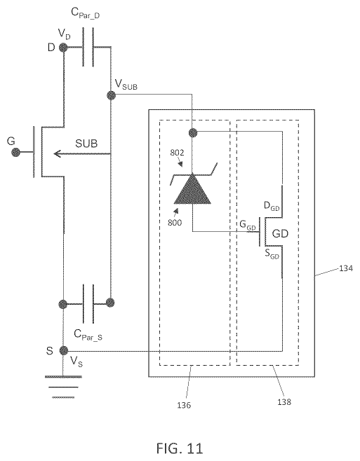

FIG. 11 illustrates a circuit schematic of the capacitive voltage divider circuit 134, according to another embodiment. In FIG. 11, the capacitive voltage divider circuit 134 includes the discharge diode device 138 electrically connected from the substrate (SUB) 100 to the source region(S) 126 of the main transistor device in a reverse direction, such that the discharge diode device 138 discharges a negative potential (−V_{SUB}) on the substrate (SUB) 100 when the transistor device switches from off to on. The capacitive voltage divider circuit 134 also includes the voltage clamp device 136 electrically connected from the substrate (SUB) 100 to the gate G_{GD} of the discharge diode device 138 in a forward direction. In FIG. 11, the voltage clamp device 136 is implemented using a diode having an anode 800 connected to the gate G_{GD} of the discharge diode device 138 and a cathode 802 connected to the substrate (SUB) 100.

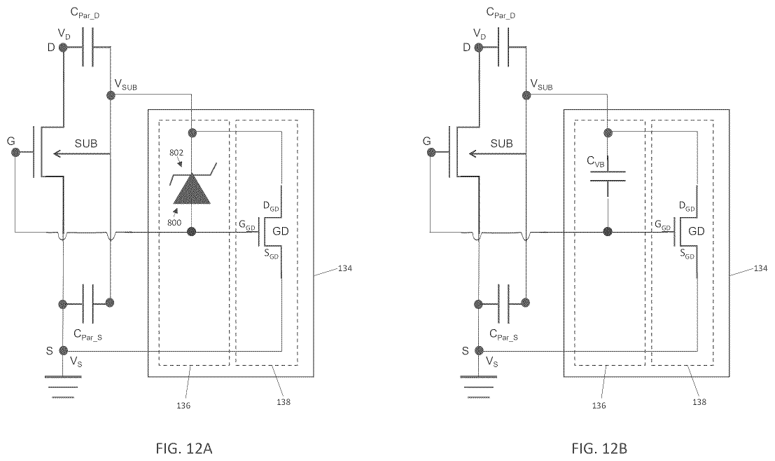

FIGS. 12A and 12B illustrate circuit schematics of the capacitive voltage divider circuit 134, according to further embodiments. The embodiment illustrated in FIG. 12A is similar to the embodiment in FIG. 11. In FIG. 12A, the anode 800 of the diode used to implement the voltage clamp device 136 and the gate G_{GD} of the discharge diode device 138 are both electrically connected to the gate (G) of the main transistor device. The embodiment illustrated in FIG. 12B is similar to the embodiment in FIG. 12A except the voltage clamp device 136 is implemented using a capacitor C_{VB} instead of a diode.

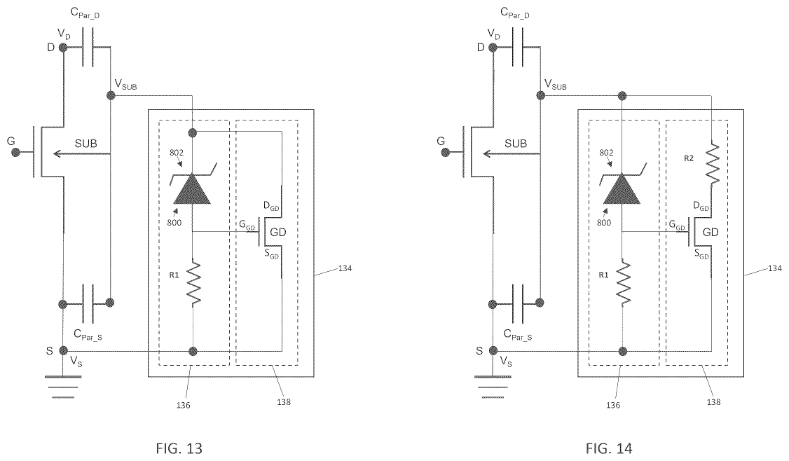

FIG. 13 illustrates a circuit schematic of the capacitive voltage divider circuit 134, according to another embodiment. The embodiment illustrated in FIG. 13 is similar to the embodiment in FIG. 11. In FIG. 13, the capacitive voltage divider circuit 134 further includes a first resistor R1 electrically connected between the gate G_{GD} and the source S_{GD} of the discharge diode device 138 configured as a gated diode. The first resistor R1 may be in a range of a few Ohms to ˜1 Mohm.

FIG. 14 illustrates a circuit schematic of the capacitive voltage divider circuit 134, according to another embodiment. The embodiment illustrated in FIG. 14 is similar to the embodiment in FIG. 13. In FIG. 14, the capacitive voltage divider circuit 134 further includes a second resistor R2 electrically connected between the drain D_{GD} of the discharge diode device 138 configured as a gated diode and the drain region 128 of the main transistor device. The second resistor R2 may be ≥10 Mohms and may be adjustable.

As previously explained herein, the capacitive voltage divider circuit 134 may include the voltage clamp device 136 but not the discharge diode device 138, the discharge diode device 138 but not the voltage clamp device 136, or both the voltage clamp device 136 and the discharge diode device 138.

Although the present disclosure is not so limited, the following numbered examples demonstrate one or more aspects of the disclosure.

Example 1. A transistor device, comprising: a substrate; an epitaxial layer stack formed on the substrate, the epitaxial layer stack including a heterojunction between two epitaxial layers having different band gaps, the heterojunction defining a channel region of the transistor device; a source terminal electrically connected to a source region of the epitaxial layer stack; a drain terminal electrically connected to a drain region of the epitaxial layer stack; a gate terminal electrically connected to a gate structure laterally between the source region and the drain region; a substrate terminal electrically connected to the substrate; and a capacitive voltage divider circuit electrically connected between the source region and the substrate, wherein in a blocking state of the transistor device, the capacitive voltage divider circuit is configured to clamp the electric potential of the substrate to a positive value.

Example 2. The transistor device of example 1, wherein the capacitive voltage divider circuit comprises a voltage clamp device electrically connected from the substrate to the source region in a forward direction.

Example 3. The transistor device of example 2, wherein the voltage clamp device comprises a chain of p-GaN diodes electrically connected in series between the substrate and the source region, wherein an anode of a first one of the p-GaN diodes in the chain is electrically connected to the substrate and a cathode of a last one of the p-GaN diodes in the chain is electrically connected to the source region.

Example 4. The transistor device of example 2, wherein the voltage clamp device comprises a chain of gated GaN diodes electrically connected in series between the substrate and the source region, wherein an anode of a first one of the gated GaN diodes in the chain is electrically connected to the substrate and a cathode of a last one of the gated GaN diodes in the chain is electrically connected to the source region.

Example 5. The transistor device of example 2, wherein the voltage clamp device comprises a chain of p-GaN diodes and gated GaN diodes electrically connected in series between the substrate and the source region, wherein an anode of a first one of the diodes in the chain is electrically connected to the substrate and a cathode of a last one of the diodes in the chain is electrically connected to the source region.

Example 6. The transistor device of any of examples 2 through 5, wherein the capacitive voltage divider circuit further comprises a discharge diode device in parallel with the voltage clamp device, and wherein the discharge diode device is configured to discharge a negative potential on the substrate when the transistor device switches from off to on.

Example 7. The transistor device of example 6, wherein the discharge diode device is a gated diode having a source electrically connected to the source region, a drain electrically connected to the substrate, and a gate electrically connected to the source of the gated diode or to the gate terminal.

Example 8. The transistor device of example 6, wherein the discharge diode device is a p-GaN diode having an anode electrically connected to the source region and a cathode electrically connected to the substrate.

Example 9. The transistor device of any of examples 2 through 8, wherein the capacitive voltage divider circuit further comprises a capacitor in parallel with the voltage clamp device.

Example 10. The transistor device of any of examples 1 through 9, wherein the capacitive voltage divider circuit comprises a capacitor electrically connected between the substrate and the source region.

Example 11. The transistor device of example 10, wherein the capacitive voltage divider circuit further comprises a discharge diode device in parallel with the capacitor, and wherein the discharge diode device is configured to discharge a negative potential on the substrate when the transistor device switches from off to on.

Example 12. The transistor device of example 11, wherein the discharge diode device is a gated diode having a source electrically connected to the source region, a drain electrically connected to the substrate, and a gate electrically connected to the source of the gated diode or to the gate terminal.

Example 13. The transistor device of example 11, wherein the discharge diode device is a p-GaN diode having an anode electrically connected to the source region and a cathode electrically connected to the substrate.

Example 14. The transistor device of any of examples 1 through 13, wherein the capacitive voltage divider circuit comprises a discharge diode device electrically connected from the substrate to the source region in a reverse direction, and wherein the discharge diode device is configured to discharge a negative potential on the substrate when the transistor device switches from off to on.

Example 15. The transistor device of example 14, wherein the discharge diode device is a gated diode having a source electrically connected to the source region, a drain electrically connected to the substrate, and a gate electrically connected to the source of the gated diode or to the gate terminal.

Example 16. The transistor device of example 14 or 15, wherein the capacitive voltage divider circuit further comprises a first resistor electrically connected between the gate and the source of the gated diode.

Example 17. The transistor device of example 16, wherein the capacitive voltage divider circuit further comprises a second resistor electrically connected between the drain of the gated diode and the drain region.

Example 18. The transistor device of any of examples 14, 16 and 17, wherein the discharge diode device is a p-GaN diode having an anode electrically connected to the source region and a cathode electrically connected to the substrate.

Example 19. The transistor device of any of examples 1 through 18, wherein the capacitive voltage divider circuit comprises: a discharge diode device electrically connected from the substrate to the source region in a reverse direction, wherein the discharge diode device is configured to discharge a negative potential on the substrate when the transistor device switches from off to on; and a voltage clamp device electrically connected between the substrate and a gate of the discharge diode device.

Example 20. The transistor device of example 19, wherein the voltage clamp device comprises a diode having an anode electrically connected to the gate of the discharge diode device and a cathode electrically connected to the substrate.

Example 21. The transistor device of example 20, wherein the anode of the diode and the gate of the discharge diode device are electrically connected to the gate terminal.

Example 22. The transistor device of example 19, wherein the voltage clamp device comprises a capacitor.

Example 23. The transistor device of example 22, wherein the capacitor and the gate of the discharge diode device are electrically connected to the gate terminal.

Example 24. A transistor device, comprising: a substrate; an epitaxial layer stack formed on the substrate, the epitaxial layer stack including a heterojunction between two epitaxial layers having different band gaps, the heterojunction defining a channel of the transistor device; a source terminal electrically connected to a source region of the epitaxial layer stack; a drain terminal electrically connected to a drain region of the epitaxial layer stack; a gate terminal electrically connected to a gate structure laterally between the source region and the drain region; a substrate terminal electrically connected to the substrate; and a capacitive voltage divider circuit electrically connected between the source region and the substrate, wherein the capacitive voltage divider circuit comprises a chain of diodes electrically connected from the substrate to the source region in a forward direction and/or a capacitor electrically connected between the substrate and the source region.

Example 25. A transistor device, comprising: a substrate; an epitaxial layer stack formed on the substrate, the epitaxial layer stack including a heterojunction between two epitaxial layers having different band gaps, the heterojunction defining a channel of the transistor device; a source terminal electrically connected to a source region of the epitaxial layer stack; a drain terminal electrically connected to a drain region of the epitaxial layer stack; a gate terminal electrically connected to a gate structure laterally between the source region and the drain region; a substrate terminal electrically connected to the substrate; and a discharge diode device electrically connected from the substrate to the source region in a reverse direction, wherein the discharge diode device is configured to discharge a negative potential on the substrate when the transistor device switches from off to on.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor device, comprising:
a substrate;
an epitaxial layer stack formed on the substrate, the epitaxial layer stack including a heterojunction between two epitaxial layers having different band gaps, the heterojunction defining a channel region of the transistor device;
a source terminal electrically connected to a source region of the epitaxial layer stack;
a drain terminal electrically connected to a drain region of the epitaxial layer stack;
a gate terminal electrically connected to a gate structure laterally between the source region and the drain region;
a substrate terminal electrically connected to the substrate; and
a capacitive voltage divider circuit electrically connected between the source region and the substrate,
wherein in a blocking state of the transistor device, the capacitive voltage divider circuit is configured to clamp the electric potential of the substrate to a positive value.

2. The transistor device of claim 1, wherein the capacitive voltage divider circuit comprises a voltage clamp device electrically connected from the substrate to the source region in a forward direction.

3. The transistor device of claim 2, wherein the voltage clamp device comprises a chain of p-GaN diodes electrically connected in series between the substrate and the source region, wherein an anode of a first one of the p-GaN diodes in the chain is electrically connected to the substrate and a cathode of a last one of the p-GaN diodes in the chain is electrically connected to the source region.

4. The transistor device of claim 2, wherein the voltage clamp device comprises a chain of gated GaN diodes electrically connected in series between the substrate and the source region, wherein an anode of a first one of the gated GaN diodes in the chain is electrically connected to the substrate and a cathode of a last one of the gated GaN diodes in the chain is electrically connected to the source region.

5. The transistor device of claim 2, wherein the voltage clamp device comprises a chain of p-GaN diodes and gated GaN diodes electrically connected in series between the substrate and the source region, wherein an anode of a first one of the diodes in the chain is electrically connected to the substrate and a cathode of a last one of the diodes in the chain is electrically connected to the source region.

6. The transistor device of claim 2, wherein the capacitive voltage divider circuit further comprises a discharge diode device in parallel with the voltage clamp device, and wherein the discharge diode device is configured to discharge a negative potential on the substrate when the transistor device switches from off to on.

7. The transistor device of claim 6, wherein the discharge diode device is a gated diode having a source electrically connected to the source region, a drain electrically connected to the substrate, and a gate electrically connected to the source of the gated diode or to the gate terminal.

8. The transistor device of claim 6, wherein the discharge diode device is a p-GaN diode having an anode electrically connected to the source region and a cathode electrically connected to the substrate.

9. The transistor device of claim 2, wherein the capacitive voltage divider circuit further comprises a capacitor in parallel with the voltage clamp device.

10. The transistor device of claim 1, wherein the capacitive voltage divider circuit comprises a capacitor electrically connected between the substrate and the source region.

11. The transistor device of claim 10, wherein the capacitive voltage divider circuit further comprises a discharge diode device in parallel with the capacitor, and wherein the discharge diode device is configured to discharge a negative potential on the substrate when the transistor device switches from off to on.

12. The transistor device of claim 11, wherein the discharge diode device is a gated diode having a source electrically connected to the source region, a drain electrically connected to the substrate, and a gate electrically connected to the source of the gated diode or to the gate terminal.

13. The transistor device of claim 11, wherein the discharge diode device is a p-GaN diode having an anode electrically connected to the source region and a cathode electrically connected to the substrate.

14. The transistor device of claim 1, wherein the capacitive voltage divider circuit comprises a discharge diode device electrically connected from the substrate to the source region in a reverse direction, and wherein the discharge diode device is configured to discharge a negative potential on the substrate when the transistor device switches from off to on.

15. The transistor device of claim 14, wherein the discharge diode device is a gated diode having a source electrically connected to the source region, a drain electrically connected to the substrate, and a gate electrically connected to the source of the gated diode or to the gate terminal.

16. The transistor device of claim 14, wherein the capacitive voltage divider circuit further comprises a first resistor electrically connected between the gate and the source of the gated diode.

17. The transistor device of claim 16, wherein the capacitive voltage divider circuit further comprises a second resistor electrically connected between the drain of the gated diode and the drain region.

18. The transistor device of claim 14, wherein the discharge diode device is a p-GaN diode having an anode electrically connected to the source region and a cathode electrically connected to the substrate.

19. The transistor device of claim 1, wherein the capacitive voltage divider circuit comprises:
a discharge diode device electrically connected from the substrate to the source region in a reverse direction, wherein the discharge diode device is configured to discharge a negative potential on the substrate when the transistor device switches from off to on; and
a voltage clamp device electrically connected between the substrate and a gate of the discharge diode device.

20. The transistor device of claim 19, wherein the voltage clamp device comprises a diode having an anode electrically connected to the gate of the discharge diode device and a cathode electrically connected to the substrate.

21. The transistor device of claim 20, wherein the anode of the diode and the gate of the discharge diode device are electrically connected to the gate terminal.

22. The transistor device of claim 19, wherein the voltage clamp device comprises a capacitor.

23. The transistor device of claim 22, wherein the capacitor and the gate of the discharge diode device are electrically connected to the gate terminal.

24. A transistor device, comprising:
a substrate;
an epitaxial layer stack formed on the substrate, the epitaxial layer stack including a heterojunction between two epitaxial layers having different band gaps, the heterojunction defining a channel of the transistor device;
a source terminal electrically connected to a source region of the epitaxial layer stack;
a drain terminal electrically connected to a drain region of the epitaxial layer stack;
a gate terminal electrically connected to a gate structure laterally between the source region and the drain region;
a substrate terminal electrically connected to the substrate; and
a capacitive voltage divider circuit electrically connected between the source region and the substrate,
wherein the capacitive voltage divider circuit comprises a chain of diodes electrically connected from the substrate to the source region in a forward direction and/or a capacitor electrically connected between the substrate and the source region.

25. A transistor device, comprising:
a substrate;
an epitaxial layer stack formed on the substrate, the epitaxial layer stack including a heterojunction between two epitaxial layers having different band gaps, the heterojunction defining a channel of the transistor device;
a source terminal electrically connected to a source region of the epitaxial layer stack;
a drain terminal electrically connected to a drain region of the epitaxial layer stack;
a gate terminal electrically connected to a gate structure laterally between the source region and the drain region;
a substrate terminal electrically connected to the substrate; and
a discharge diode device electrically connected from the substrate to the source region in a reverse direction,
wherein the discharge diode device is configured to discharge a negative potential on the substrate when the transistor device switches from off to on.
